(19) United States
(12) Patent Application Publication
(10) Pub. No.: US 2026/0324486 A1
(43) Pub. Date: Oct. 15, 2026

(54) PACKAGING ASSEMBLY AND ASSEMBLING METHOD THEREOF, AND CAMERA MODULE

(71) Applicant: NINGBO SUNNY OPOTECH CO., LTD, Zhejiang (CN)

(72) Inventors: Zhongyu LUAN, Zhejiang (CN); Jie YU, Zhejiang (CN); Li LIU, Zhejiang (CN); Ji BAO, Zhejiang (CN); Xisong LU, Zhejiang (CN); Xinlei LI, Zhejiang (CN); Zhiyi ZHOU, Zhejiang (CN); Jiale LIU, Zhejiang (CN); Fangqi CHEN, Zhejiang (CN); Mingxuan WANG, Zhejiang (CN); Jiawei CHEN, Zhejiang (CN)

(73) Assignee: NINGBO SUNNY OPOTECH CO., LTD, Zhejiang (CN)

(21) Appl. No.: 19/485,491

(22) PCT Filed: Jun. 12, 2024
(86) PCT No.: PCT/CN2024/098696

§ 371 Date: Nov. 18, 2025

(30) Foreign Application Priority Data
Jun. 15, 2023 (CN) 202310713292.2
Jun. 15, 2023 (CN) 202310714337.8

(51) Int. Cl. H10W 72/20; H04N 23/54; H04N 23/55; H10W 74/10

(52) U.S. Cl. CPC H10W 72/257; H04N 23/54; H04N 23/55; H10W 72/231; H10W 72/244; H10W 72/252; H10W 74/121

(57) ABSTRACT

Disclosed in the present invention are a packaging assembly and an assembling method thereof, and a camera module. The assembling method for the packaging assembly comprises the steps of: a. providing a circuit board, wherein one side surface of the circuit board is provided with a plurality of circuit board pads, and implanting at least one solder ball into said circuit board pads; b. providing a chip, wherein the chip is provided with a plurality of chip pads, and implanting at least one gold ball into said chip pads; c. applying adhesive to the solder ball of the circuit board pads; and d. aligning the chip pads with the circuit board pads, and bonding and fixing the solder ball of the circuit board pads and the gold ball of the chip pads so as to connect the circuit board and the chip. By applying adhesive to fill a molten area formed by the gold ball and the solder ball, the packaging assembly is provided with the advantages of good conductivity, low overall weight, a small size, etc., so that the packaging assembly can be applied to camera module structures such as those with chip-based optical image stabilization, thereby effectively improving the adjustment precision of chip-based optical image stabilization.

### TECHNICAL FIELD

The present application relates to the technical field of camera modules, particularly to a packaging assembly and an assembling method thereof, and a camera module assembled by the packaging assembly.

### BACKGROUND ART

A camera module is one of the indispensable components of smart electronic devices, including but not limited to: smart phones, cameras, computer equipment, wearable devices, etc. With the continuous development and popularization of various smart devices, the requirements for camera modules are becoming higher and higher.

In recent years, smart electronic devices have developed by leaps and bounds, and are becoming increasingly thinner and lighter. In order to adapt to this development, camera modules are increasingly required to be multifunctional, thinner, and smaller, so that electronic devices can be made thinner and thinner, and meet the imaging requirements of the device for the camera module. Therefore, camera module manufacturers are committed to design and manufacture camera modules that meet these requirements.

Taking smartphones as an example, the phone bodies are becoming thinner and lighter, so the camera modules are also required to become thinner and lighter. A camera module is mainly composed of an optical lens and a chip packaging assembly. The height of the optical lens is currently difficult to optimize, so the thinness of the camera module mainly depends on the size of the chip packaging assembly. At present, in order to improve the imaging quality of the camera module, the size of the imaging surface of the chip is rapidly increasing, but at the same time it needs to cater to the trend of lightweight and thinness of the smart devices. Even if the chip size increases, the height size of the overall camera module is still limited. Furthermore, how to reduce the height and size of the chip packaging assembly when the chip size increases is an important issue that needs to be solved at present.

A camera module is an optical electronic device, and its chip packaging assembly not only needs to consider the stability of the chip circuit conduction, but also needs to ensure the stability of the structure. After the chip and the circuit board structure are conductively connected, the stability of the connection between the chip and the circuit board must also be ensured. The chip and circuit board packaging assembly need to undergo a plurality of reliability tests during the manufacturing process. If the structure of a packaging assembly from the chip and the circuit board is unstable, the chip will fall off the circuit board during the reliability test, thereby destroying the stability of the structure of the packaging assembly. How to structurally ensure the stability of the connection between the chip and the circuit board is also one of the issues that need to be considered at present.

To sum up, at the time of providing a chip and circuit board packaging structure that can achieve the miniaturization of the structure of a packaging assembly, it is also necessary to consider the stability of the packaging assembly structure and the chip conduction problem, and it is necessary to consider electrical, optical and structural factors comprehensively, but these factors are obviously not taken into consideration in combination in the prior art.

### SUMMARY

In view of the above problems, the present application provides a packaging assembly structure of a chip and a circuit board, which can effectively solve some and/or most of the above problems while achieving miniaturization of the overall structure of the packaging assembly.

One object of the present application is to provide a packaging assembly, an assembling method thereof and a camera module, wherein the packaging assembly has a simple structure and can ensure the miniaturization of the overall packaging assembly while realizing its assembly in the camera module, thereby realizing the lightness and thinness of the camera module structure.

Another object of the present application is to provide a packaging assembly, an assembling method thereof and a camera module, wherein a conductive bonding area is formed between the chip and the circuit board by bonding the gold ball fixed on the chip pad with the solder ball on the circuit board pad, thereby conductively connecting the circuit board to the photosensitive chip.

Another object of the present application is to provide a packaging assembly, an assembling method thereof and a camera module, wherein a circuit board pad is provided on the back of the circuit board, and a solder ball is provided on the circuit board pad by stencil printing process, so that the solder ball can be fixed on the circuit board pad to ensure stable conductive connection with the chip.

Another object of the present application is to provide a packaging assembly, an assembling method thereof and a camera module, wherein adhesive is applied onto the circuit board pad, so that the adhesive covers the solder ball to avoid oxidation of the solder ball and facilitate melting the solder ball with the gold ball.

Another object of the present application is to provide a packaging assembly, an assembling method thereof and a camera module, wherein a chip pad is provided on the front surface of the chip, and a gold ball is provided on the chip pad, so that the gold ball is conductively connected to the chip pad, thereby further extending the conductive circuit of the chip to facilitate conductive connection with the circuit board.

Another object of the present application is to provide a packaging assembly, an assembling method thereof and a camera module, wherein adhesive is filled in the gap inside the conductive bonding area formed by the circuit board and the chip, so as to make the connection between the chip and the circuit board more stable, thereby preventing the chip from falling off the circuit board, and improving the reliability of the packaging assembly.

Another object of the present application is to provide a packaging assembly, an assembling method thereof and a camera module, wherein a through hole is formed on the circuit board, the chip is arranged on the circuit board, and the effective area of the chip corresponds to the through hole of the circuit board, and the surface of the effective area of the chip is lower than the front surface of the circuit board, thereby effectively reducing the height of the packaging assembly.

Another object of the present application is to provide a packaging assembly, an assembling method thereof and a camera module, wherein the chip is fixed on the circuit board, and the chip is mainly fixed on the back of the circuit board, so that the effective area of the chip is completely exposed in the through hole of the circuit board to ensure that the chip can receive most of the external light.

Another object of the present application is to provide a packaging assembly, an assembling method thereof and a camera module, wherein electronic components are provided and fixed on the circuit board by a molding process, and the electronic components are molded inside the circuit board, thereby effectively preventing the electronic components from falling off.

Another object of the present application is to provide a packaging assembly, an assembling method thereof and a camera module, wherein a molding portion is formed on the circuit board by molding process, and the molding portion can form a color filter mounting position on its upper surface at the same time of covering the electronic components, thereby ensuring the accuracy of color filter installation.

Another object of the present application is to provide a packaging assembly, an assembling method thereof and a camera module, wherein a back molding portion is formed on the back side of the circuit board, and there is a gap between the back molding portion and the chip, and the back molding portion can further strengthen the structural strength of the packaging assembly.

Another object of the present application is to provide a packaging assembly, an assembling method thereof and a camera module, wherein the packaging assembly is arranged on a driving assembly to form a structure for chip-based optical image stabilization, and this structure for chip-based optical image stabilization is combined with an optical lens to obtain a camera module structure with a large-stroke of chip-based optical image stabilization.

In order to achieve the above objects, the technical solutions adopted by the present application are as follows:

A packaging assembly comprises: a circuit board and a chip, wherein the circuit board is provided with a through hole, and the chip is arranged corresponding to the through hole of the circuit board, wherein:
a plurality of circuit board pads are provided on the circuit board, and at least one solder ball is arranged on each of the circuit board pads, and a plurality of chip pads are provided on the chip, and at least one gold ball is arranged on the chip pad, and the chip pad corresponds to the circuit board pad, and at least one gold ball is melted with at least one solder ball to form a conductive bonding area to conduct the circuit board and the chip;
there are gaps between a plurality of conductive bonding areas where the gold balls are melted with the solder balls, and the gaps are filled with adhesive.

In a particular example, the gold balls are fixed with the solder balls by thermal compression bonding.

In a particular example, the adhesive contains flux and covers the solder balls, thereby slowing down oxidation of the solder balls.

In a particular example, the adhesive connects the circuit board and the chip, and completely fills the gaps between a plurality of conductive bonding areas where the gold balls are melted with the solder balls.

In a particular example, the adhesive is arranged around the through hole of the circuit board and covers the circuit board pads, wherein the adhesive has a adhesive bead width, and the solder balls are arranged on a side of the midline of the adhesive bead width which is close to the through hole of the circuit board, so that the adhesive can cover the solder balls therein.

In a particular example, the thickness of the adhesive is greater than the height of the solder ball, and the thickness of the adhesive is greater than or equal to 20 μm.

In a particular example, an ink structure is provided on the circuit board, and the ink is respectively provided on both sides which are close to and away from the through hole of the circuit board, wherein the ink is protrudingly provided on the circuit board pad to form a groove, and the circuit board pad is at least partially accommodated in the groove.

In a particular example, the solder ball is arranged on the circuit board pad, and the solder ball covers at least 80% of the area of the circuit board pad, so that the solder ball is accommodated in the groove formed by the ink structure.

In a particular example, the gold ball on the chip pad has a protrusion portion, wherein the protrusion portion extends into the interior of the solder ball on the circuit board pad to increase the contact area between the solder ball and the gold ball.

In a particular example, the circuit board pads are arranged corresponding to the chip pads, wherein the center distance between at least some adjacent circuit board pads is less than 150 μm.

In a particular example, the packaging assembly further comprises a molding portion which is integrally formed on the circuit board, wherein the molding portion comprises a front molding portion and a back molding portion formed on the front and back surfaces of the circuit board.

In a particular example, the back molding portion is arranged on the back surface of the circuit board, and the back molding portion can be used to strengthen the strength of the circuit board, wherein the lower surface of the back molding portion is lower than the back surface of the chip.

In a particular example, the front molding portion is arranged in a ring shape around the through hole of the circuit board, and the front surface of the circuit board provided with the circuit board pad is covered by the front molding portion.

In a particular example, a camera module is further provided, wherein the camera module comprises:
a lens motor, and
the packaging assembly described above;
wherein the lens motor is arranged on the upper surface of the packaging assembly so that external light can reach the interior of the packaging assembly through the lens motor.

An assembling method of a packaging assembly comprises the steps of:
a) providing a circuit board, wherein a plurality of circuit board pads are provided on one surface of the circuit board, and at least one solder ball is implanted into the circuit board pad;
b) providing a chip, wherein a plurality of chip pads are provided on the chip, and at least one gold ball is implanted into the chip pad;
c) applying adhesive onto the solder balls of the circuit board pads; and
d) aligning the chip pads with the circuit board pads, and bonding and fixing the solder balls of the circuit board pads with the gold balls of the chip pads to conduct the circuit board and the chip.

In a particular example, the adhesive in step c) contains flux and is applied onto the circuit board pads to cover the solder balls.

In a particular example, the step c) particularly comprises the steps of: applying the adhesive onto the circuit board pads through a adhesive dispensing process, so that the solder balls are located on a side of the midline of the adhesive bead width which is close to the center of the circuit board, so that the adhesive covers the solder ball therein.

In a particular example, the thickness of the adhesive is greater than the height of the solder ball.

In a particular example, the step d) particularly comprises the steps of: fixing the solder balls of the circuit board pads and the gold balls of the chip pads by thermal compression bonding, so that at least one solder ball is melted with at least one gold ball to form a conductive bonding area, while the adhesive is filled in the gaps between the conductive bonding areas.

In a particular example, the temperature of the thermal compression bonding of the solder ball and the gold ball is controlled, and the bonding process is step-by-step heated with a first bonding temperature and a second bonding temperature so that the adhesive fills the conductive bonding area between the chip and the circuit board, wherein the first bonding temperature is used for a relatively short time, and the heating time of the second bonding temperature is 5 times or more than that of the first bonding temperature.

In a particular example, the step d) particularly comprises: forming a protrusion portion on the gold ball of the chip pad, aligning it with the solder ball of the circuit board pad, and extending the protrusion portion of the gold ball into the solder ball of the circuit board pad to increase the contact area between the solder ball and the gold ball.

In a particular example, the step a) particularly comprises the steps of: depositing solder paste on the circuit board pad by stencil printing, forming the solder paste into the solder balls by reflow soldering and implanting them into the circuit board pad.

In a particular example, the step a) particularly comprises: protrudingly arranging an ink structure on the circuit board to form a groove, so that the circuit board pad is at least partially accommodated in the groove, and the solder ball covers at least 80% of the area of the circuit board pad, thus the solder ball can be accommodated in the groove formed by the ink structure on the circuit board.

In a particular example, the step a) further comprises step a1): integrally forming a circuit board front molding portion on the front surface of the circuit board, and integrally forming a circuit board back molding portion on the back surface of the circuit board, so that the circuit board back molding portion is arranged on the outside of the circuit board pad.

In a particular example, the step a) further comprises step a2): forming a through hole on the circuit board, wherein the through hole passes through the central area of the circuit board, and the front molding portion of the circuit board is arranged in a ring shape around the through hole.

In a particular example, the method further comprises step e): installing a color filter on a color filter mounting position on the front molding portion of the circuit board to filter out stray light.

In a particular example, a camera module is further provided, wherein the camera module comprises:
a lens motor; and
a packaging assembly manufactured by the above assembling method of a packaging assembly, wherein the lens motor is arranged on the upper surface of the packaging assembly so that external light can reach the interior of the packaging assembly through the lens motor.

### BRIEF DESCRIPTION OF THE DRAWINGS

By describing the examples of the present application in more detail in conjunction with the accompanying drawings, the above and other objects, features and advantages of the present application will become more apparent. The accompanying drawings are used to provide further understanding of the examples of the present application and constitute a part of the specification, they are used together with the examples of the present application to explain the present application and do not constitute a limitation on the present application. In the drawings, identical reference numerals generally represent the same components or steps.

FIG. 1 is a schematic diagram of a common packaging assembly structure in the prior art according to the present application;

FIG. 2 is a schematic diagram of a particular example of a packaging assembly structure according to the present application;

FIG. 3 is a schematic diagram of another particular example of the packaging assembly structure according to the present application;

FIG. 4 is a partial schematic diagram of the conductive connection between the circuit board and the chip in the packaging assembly structure according to the present application;

FIG. 5 is another partial schematic diagram of the conductive connection between the circuit board and the chip in the packaging assembly structure according to the present application;

FIG. 6 is a schematic diagram of the structure of the stencil-printed solder ball on the circuit board according to the present application;

FIG. 7 is a schematic diagram of the back structure of the circuit board according to the present application;

FIG. 8A is a partial schematic diagram of the assembly process of the packaging assembly according to the present application;

FIG. 8B is a partial schematic diagram of the assembly process of the packaging assembly according to the present application, wherein FIG. 8A and FIG. 8B show the complete steps of assembling the entire packaging assembly;

FIG. 9 is a partial schematic diagram of the solder balls and adhesive on the back of the circuit board according to the present application;

FIG. 10 is a partial schematic diagram of the ink structure on the back of the circuit board according to the present application;

FIG. 11 is a schematic diagram of the structure of a camera module assembled with this packaging assembly structure according to the present application.

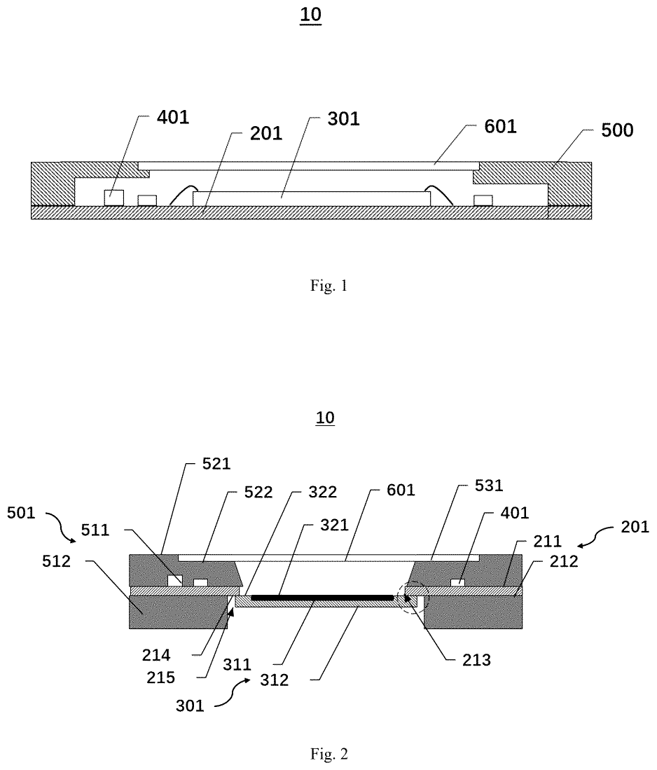

### DETAILED DESCRIPTION

The present application is further described below in conjunction with specific implementation methods. It should be noted that, under the premise of no conflict, the various examples or technical features described below can be arbitrarily combined to form new examples.

The present application is further described below in conjunction with specific implementation methods. It should be noted that, under the premise of no conflict, the various examples or technical features described below can be arbitrarily combined to form new examples.

In the description of the present application, it should be noted that directional words, such as the terms “center”, “lateral”, “longitudinal”, “length”, “width”, “thickness”, “up”, “down”, “front”, “back”, “left”, “right”, “vertical”, “horizontal”, “top”, “bottom”, “inside”, “outside”, “clockwise”, “counterclockwise”, etc., indicating directions and positional relationships are based on the directions or positional relationships shown in the accompanying drawings, which are only for the convenience of narrating the present application and simplifying the description, and do not indicate or imply that the device or component referred to must have a specific orientation, be constructed and operated in a specific orientation, and cannot be understood as limiting the specific protection scope of the present application.

It should be noted that, the terms “first”, “second”, etc. in the description and claims of this application are used to distinguish similar objects, and are not necessarily used to describe a specific order or sequence.

The terms “include/comprise/have” and “including/comprising/having” and any variations thereof in the specification and claims of this application are intended to cover non-exclusive inclusions. For example, a process, method, system, product or device comprising a series of steps or units is not necessarily limited to those steps or units explicitly listed, but may comprise other steps or units not explicitly listed or inherent to these processes, methods, products or devices.

In the description of the present application, it should also be noted that, unless otherwise clearly specified and limited, the terms “provided/arranged”, “installed”, “connected” and “connection” should be understood in a broad sense. For example, it can be a fixed connection, a detachable connection, or an integral connection; it can be a mechanical connection or an electrical connection; it can be a direct connection, a contact connection, or an indirect connection through an intermediate medium; and it can be the internal connection of two components. For those skilled in the art, the specific meanings of the above terms in this application can be understood according to specific circumstances.

As the most important electronic component in a camera module, the photosensitive chip can convert external light signals into electrical signals, and it is one of the indispensable components in the camera module. Typically, the chip is arranged on the upper surface of a circuit board, and the chip and the circuit board are connected by wire bonding (WB) process to ensure normal operation of the chip. However, as the requirements for the imaging quality of camera modules increase, the chip size also increases accordingly, and the size of the circuit board on which the chip is mounted will also increase accordingly. At the same time, the stacking of the chip and circuit board results in a large height dimension, which is not in line with the current trend of lightweight and thin for the camera module structures.

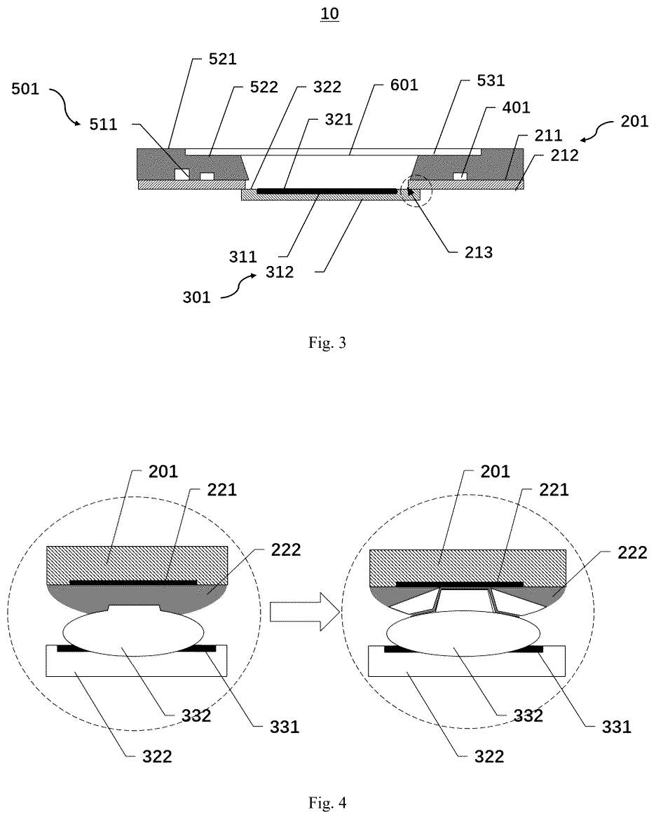

The present application provides a packaging assembly 10 comprising a chip. In order to improve the imaging quality of a camera module, the size of the chip is increased accordingly, and the size of the corresponding circuit board connected to the chip also needs to be increased. In order to reduce the size of the chip and the circuit board after packaging, the structure of the circuit board and the chip is also improved accordingly. Particularly, in the present application, the chip size is greater than/equal to 1/1.7 inch. As shown in FIGS. 2-3, the chip 301 comprises an effective area 321 and a non-effective area 322, wherein the effective area 321 is located in the middle of the chip 301, and the non-effective area 322 is located at the edge of the chip 301. The size of the circuit board 201 is larger than that of the chip 301. Furthermore, a corresponding through hole 213 of the circuit board is provided in the middle of the circuit board 201. The size of the through hole 213 of the circuit board is larger than or equal to the size of the effective area 321 of the chip 301, that is, the effective area 321 of the chip is exposed in the through hole 213 of the circuit board formed in the circuit board 201, and the non-effective area 322 of the chip 301 is connected to the circuit board 201.

Particularly, the circuit board 201 and the chip 301 need to be conductively connected, and the end surface of the circuit board 201 in contact with the chip 301 is defined as the back surface 212 of the circuit board, and the end surface of the circuit board 201 away from the chip 301 is defined as the front surface 211 of the circuit board. In the present application, the through hole 213 of the circuit board passes through the front surface 211 of the circuit board and the back surface 212 of the circuit board, and the circuit board pad 221 is arranged on the back surface 212 of the circuit board around the through hole 213 of the circuit board. Particularly, the circuit board pad 221 may be arranged on at least one side of the through hole 213 of the circuit board, alternatively, depending on the need for conduction, the circuit board pad 221 may be arranged on all four sides of the through hole 213 of the circuit board, and no specific limitation is made herein. Furthermore, the end surface of the chip 301 in contact with the circuit board 201 is defined as the front surface 311 of the chip, and the end surface of the chip 301 away from the circuit board 201 is defined as the back surface 312 of the chip, wherein the chip pad 331 is arranged on the front surface 311 of the chip, particularly the chip pad 331 is arranged in the non-effective area 322 of the chip.

When the chip 301 is arranged in the through hole 213 of the circuit board, the effective area 321 of the chip is exposed in the through hole 213 of the circuit board. Furthermore, at the portion where the back surface 212 of the circuit board contacts with the non-effective area 322 of the chip, the circuit board pad 221 is adapted to the chip pad 331. That is to say, the circuit board pad 221 on the back surface 212 of the circuit board and the chip pad 331 on the front surface 311 of the chip are in a one-to-one correspondence, so that conduction is achieved between the circuit board 201 and the chip 301. The direct contact between the circuit board pad 221 and the chip pad 331 cannot guarantee stable conduction between the two. In order to further ensure the stability of conduction between the chip 301 and the circuit board 201, other methods are needed to ensure stable conduction between the chip 301 and the circuit board 201.

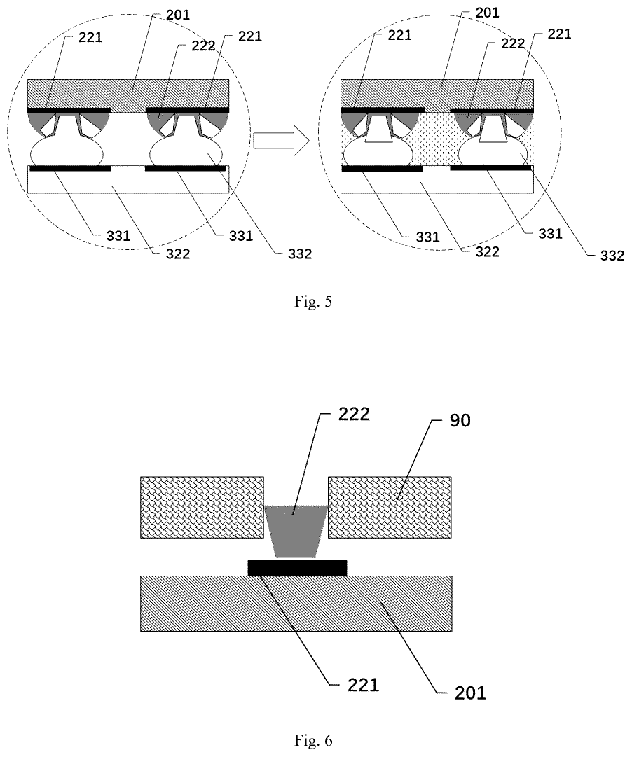

The present application further provides a method for conducting the chip 301 with the circuit board 201. As shown in FIGS. 4-5, in a particular example, when the chip 301 is arranged in the through hole 213 of the circuit board 201, the circuit board pad 221 on the back surface 212 of the circuit board contacts with the chip pad 331 on the front surface 311 of the chip. In order to ensure the efficiency of electrical conduction between the chip 301 and the circuit board 201, materials with good electrical conductivity such as copper, gold, etc. are preferably selected. In the present application, gold balls 332 are preferably used to conductively connect the chip 301 with the circuit board 201. Particularly, the gold ball 332 is implanted on the chip pad 331 so that one end of the gold ball 332 contacts with the chip 301, and the other end of the gold ball 332 contacts with the circuit board pad 221, and the gold ball 332 is used as an intermediate medium for the circuit board 201 and the chip 301 to conductively connect with each other, so that the chip 301 and the circuit board 201 are conducted.

Furthermore, although the gold ball 332 has good conductivity, so that the chip 301 is conductively connected to the circuit board 201, the circuit board pad 221 is generally made from metal copper, and copper and gold are not fusible, so the chip 301 is easy to fall off the circuit board 201. In order to ensure good conduction and stable connection between the chip 301 and the circuit board 201. In the present application, a method is provided to ensure stable conduction between the chip 301 and the circuit board 201. Particularly, a Sn—Au (tin-gold) compound is used for conduction, a solder ball 222 is provided on the circuit board pad 221, and the gold ball 332 is implanted on the chip pad 331, so that the solder ball 222 on the circuit board 201 is in contact with the gold ball 332 on the chip 301, thereby effectively ensuring the circuit conduction between the circuit board 201 and the chip 301.

Particularly, the gold ball 332 on the chip 301 is melted with the solder ball 222 on the circuit board 201, and the tin-gold compound layer 223 is formed at the position where the gold ball 332 contacts with the solder ball 222. The tin-gold compound layer 223 is a compound formed by gold and tin under heating conditions, and can be bonded to the solder ball 222 on the circuit board pad 221 and the gold ball 332 on the chip pad 331, thereby ensuring the stability of the connection between the chip 301 and the circuit board 201. In a particular example, after the solder ball 222 on the circuit board pad 221 and the gold ball 332 on the chip pad 331 are melted with each other, the chip 301 and the circuit board 201 are conductively connected to form a conductive bonding area, and a plurality of the tin-gold compound layers 223 can be formed in the conductive bonding area. An intermediate material layer is formed at the connection between the solder ball 222 and the gold ball 332 so as to assist the solder ball 222 to be melted with the gold ball 332, thereby preventing the gold ball 332 and the solder ball 222 from being difficult to fuse due to different chemical properties, and avoiding the chip 301 to fall off the circuit board 201.

Furthermore, in order to make the connection between the chip 301 and the circuit board 201 more stable, it is necessary to further increase the contact area between the gold ball 332 on the chip 301 and the solder ball 222 on the circuit board 201. The material of the chip pad 331 is generally gold, so when the gold ball 332 is implanted on the chip pad 331, the gold ball 332 and the chip pad 331 can be well melted. Particularly, the gold ball 332 has a protrusion portion, which is directed toward the direction of the circuit board pad 221, wherein the protrusion portion of the gold ball 332 on the chip 301 extends into the solder ball 222 of the circuit board pad 221 so as to increase the contact area between the solder ball 222 and the gold ball 332. In order to fuse the solder ball 222 on the circuit board with the gold ball 332 on the chip, a corresponding soldering flux is provided in the middle position where the two are in contact. Rosin can be selected as the soldering flux. Its main function is to prevent the solder ball from being oxidized when the tin powder is melted into the solder ball, so that the solder ball 222 on the circuit board pad 221 and the gold ball 332 on the chip pad 331 can be better melted with each other, and the stability of the electrical conduction between the circuit board 201 and the chip 301 can be ensured.

In the present application, as shown in FIGS. 4-5, the gold ball 332 is implanted on the chip pad 331 so that it is melted with the solder ball 222 arranged on the circuit board pad 221. However, the contact area between the solder ball 222 and the gold ball 332 is limited, in the subsequent reliability process, the chip 301 is easily detached from the circuit board 201, which does not meet the reliability requirements. In order to further enhance the stability of the connection between the circuit board 201 and the chip 301, adhesive 232 is used to fill the gap between the solder ball 222 on the circuit board 201 and the gold ball 332 on the chip 301 at the connection between the circuit board 201 and the chip 301. The adhesive 232 connects the circuit board 201 and the chip 301. In some optional examples, the adhesive 232 completely fills the gap between a plurality of the conductive bonding areas where the gold balls 332 are melted with the solder balls 222. The range of the complete filling means that the filling range of the adhesive in the gap between the conductive bonding areas is more than 80%. Particularly, the height of the adhesive 232 is greater than the height of the solder ball 222, so that the solder ball 222 is covered inside the adhesive 232 so as to prevent the solder ball 222 from contacting with external air, thereby preventing the solder ball 222 from being oxidized. The adhesive 232 contains flux to make the solder ball 222 to be fully melted with the gold ball 332. Meanwhile, the circuit board 201 and the chip 3012 are in full contact with the adhesive 232. Due to the viscosity of the adhesive 232 itself, the stability of the connection between the circuit board 201 and the chip 301 is enhanced.

In a particular example, if only the solder ball 222 on the circuit board 201 is melted with the gold ball 332 on the chip 301, although the chip 301 can be effectively connected, the simulation model can measure that the tolerable thrust for the bonding area between the chip 301 and the circuit board 201 is approximately 0.7 kg, which does not meet the reliability requirements. In the present application, by adding adhesive 232 to the bonding area between the chip 301 and the circuit board 201, and utilizing the adhesive force of the adhesive 232 to enhance the stability of the connection between the circuit board 201 and the chip 301, the tolerable thrust for the bonding area between the chip 301 and the circuit board 201 can be increased to 2.7 kg, thereby satisfying the reliability requirements for the design of the packaging assembly 10 of a camera module.

Furthermore, adhesive 232 is provided in the bonding area between the chip 301 and the circuit board 201. The specific model of the adhesive 232 can be selected according to the actual design and is not limited accordingly. The method for providing the adhesive 232 in the present application can adopt a adhesive dispensing process. The adhesive 232 is provided around the through hole 213 of the circuit board and covers the circuit board pad 221, wherein the adhesive 232 has a adhesive bead width, and the solder ball 222 is arranged on a side of the midline of the adhesive bead width close to the through hole 213 of the circuit board, so that the adhesive 232 can cover the solder ball 222 therein. Particularly, the adhesive bead width refers to the width of the adhesive 232 when it is applied to the circuit board 201, and generally refers to the width of the adhesive in the direction extending from the through hole 213 of the circuit board to the outer edge of the circuit board. Particularly, due to the limited spatial position of the connection between the circuit board 201 and the chip 301, the diameter of the needle for dispensing adhesive selected in the present application is 0.01 mm, and the width of the dispensed adhesive is less than or equal to 20 μm. At the same time, during the process of fixing the adhesive 232, if the temperature is not controlled accordingly, the adhesive 232 will trap air during the sudden temperature rise, resulting in insufficient bonding area between the chip 301 and the circuit board 201. Therefore, it is also necessary to control the temperature to meet the step-by-step temperature rise of the bonding, the temperature of the thermal compression bonding of the solder ball and the gold ball is controlled to rise the temperature of the bonding process step-by-step through the first bonding temperature and the second bonding temperature, wherein the first bonding temperature is a relatively low temperature in a temperature range of 100° C.-200° C., and the heating time is relatively short, so that the bubbles in the adhesive 232 are reduced to increase the bonding area between the adhesive 232 and the circuit board 201 or the chip 301, thereby increasing the bonding force; and the second bonding temperature range is between 200° C.-300° C., and the heating time is more than 5 times the heating time of the first bonding temperature, so that the adhesive can fully fill the conductive bonding area between the chip and the circuit board, thus the adhesive 232 can completely cover the bonding area between the chip and the circuit board.

Particularly, each of the chip 301 and the circuit board 201 is provided with pads, especially the chip pad 331, which is relatively small (usually not visible to the naked eye, but can be seen with the help of corresponding instruments). To implant the gold ball 332 on the chip pad 331, some special processes are required, such as laser solder bumping, splicing laser solder bumping, stencil printing plus reflow soldering or stencil printing. Furthermore, in the present application, the gold ball 332 can be implanted onto the chip pad 331 by stencil printing process, so that the chip 301 is conductively connected to the circuit board 201 to ensure the normal operation of the chip 301.

Furthermore, a corresponding solder ball 222 is also required to be provided on the circuit board pad 221. The gold ball 332 on the chip is melted with the solder ball 222 on the circuit board 201, so that the circuit board 201 is conductive connected with the chip 301. Since the size of the circuit board pad 221 is also relatively small, a special process is also required to implant the solder ball 222 on the circuit board 201. Particularly, in the present application, a corresponding solder ball 222 needs to be arranged on the circuit board pad 221, and the solder ball 222 needs to be in contact with the circuit board pad 221 as much as possible to ensure the stability of the connection of the solder ball 222 on the circuit board 201. Preferably, in order to make the solder ball 222 in good contact with the circuit board pad 221, the stencil printing process is chosen to be used in the present application, that is, the printing direction of the stencil 90 is consistent with the arrangement direction of the circuit board pad 221, thereby reducing the occurrence of bridging/insufficient tin phenomenon.

Particularly, an ink structure 231 is provided on the circuit board 201, and the ink structure 231 is respectively arranged on both sides which close to and away from the through hole 213 of the circuit board, wherein the ink is protrudingly arranged on the circuit board pad 221 and forms a groove, and the circuit board pad 221 is at least partially accommodated in the groove. Furthermore, in the present solution, the chip 301 is fixed on the back surface of the circuit board 201. In order to accurately identify the center of the circuit board 201 and enable the chip 301 to be accurately installed on the circuit board 201, in another feasible example, a corresponding ink layer is further provided on the back surface 212 of the circuit board to identify the center of the circuit board 201, so that the center of the chip 301 installed on the circuit board 201 is consistent with the center of the circuit board 201.

Particularly, in order to match the size of the circuit board 201 in the present application, as shown in FIG. 6, the openings of the stencil 90 can be designed with a diameter of 70 μm and a thickness of 30 μm. In other solutions, the corresponding design can be made according to the size of the actual product, as long as it is ensured that no bridging/insufficient tin and other phenomena exist. Particularly, in order to prevent the adhesion between the solder paste and the surface of the stencil 90 from forming resistance to the connection between the solder ball 222 and the circuit board 201 and affecting the transfer amount of the solder paste, the design of the stencil 90 needs to meet certain requirements. For example, in the present application, the gaps of the stencil 90 can be a rectangular structure. The specific size parameters of the stencil 90 can be determined according to the actual product structure, and no corresponding explanation is given here.

In the present application, the main material of the circuit board pad 221 is gold, and the main material of the solder ball 222 implanted on the circuit board is tin. Since tin and gold are two materials with different properties, the performance of these two materials will be unstable as the external environment changes. For example, the solder ball 222 is easily oxidized when exposed to the air for a long time. In order to improve this situation, in the present application, flux is added to the solder paste so that the solder ball 222 and the circuit board pad 221 can be better melted with each other, wherein the main component of the flux is rosin, and its function is to prevent the solder ball 222 from being oxidized when the tin powder is melted into the solder ball. The flux is directly added to the solder paste, and the reflow soldering process is used when the solder paste is melted into the solder ball 222. It is worth mentioning that, the adhesive also contains flux and is applied to the circuit board pad 221 to cover the solder ball 222, thereby preventing the solder ball 222 from being oxidized.

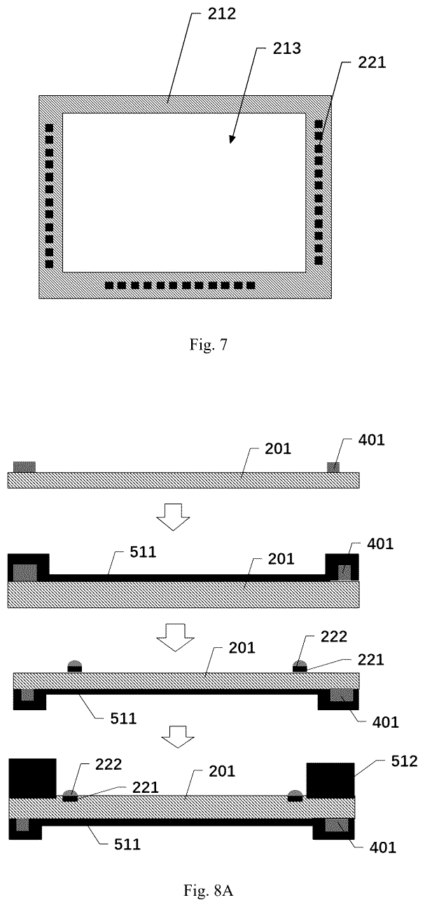

Furthermore, as shown in FIG. 7, during the conduction between the circuit board pad 221 and the chip 301, the circuit board 201 needs to be heated, and the material constituting the circuit board 201 itself will deform due to temperature changes, resulting in inaccurate center positioning of the circuit board 201 during the subsequent assembly of the circuit board 201 and the chip 301, and causing a deviation in the mounting position of the chip 301 on the circuit board 201, thus the circuit board pad 221 and the chip pad 331 cannot be aligned one by one, resulting in unstable conduction between the circuit board 201 and the chip 301. The amount of copper used in the circuit board 201 is increased. Since the property of metal copper are relatively stable, and its expansion and contraction under the influence of temperature are relatively small, the deformation of the circuit board 201 during the conduction process can be reduced, thereby improving the installation accuracy of the chip 301 on the circuit board 201. At the same time, increasing the copper content of the circuit board 201 can also reduce the deformation of the through hole 213 of the circuit board.

In the present application, as shown in FIGS. 6-7, generally, the solder ball 222 is provided on the circuit board pad 221 by stencil printing process. Compared with the conventional solution (there is a solder resist between the pads, and the gap of the solder resist is greater than 150 μm), in order to reduce the size occupied by the part of the circuit board 201, the gap between the circuit board pads 221 in the present solution is less than 40 μm, so the use of conventional printing technology will cause problems such as tin-bridging. In the present solution, the solder ball 222 is arranged on the circuit board pad 221 through the stencil printing process. In addition to limiting the size design of the stencil 90 (the specific size of the stencil 90 can be referred to the above description), it is also necessary to provide a solder resist between the circuit board pads 221, wherein the width of the solder resist is greater than or equal to the width of the gap between two adjacent pads on the circuit board. Furthermore, the solder resist arranged between the circuit board pads 221 is incompatible with the solder paste itself. The solder resist between the circuit board pads 221 can be eliminated by subsequent heating or other special processes, thereby avoiding problems such as tin-bridging between the circuit board pads 221. The above solution can effectively reduce the area of the bonding region between the chip and the circuit board, and improve the accuracy of bonding conduction, thereby meeting the miniaturization requirements of the packaging assembly 10.

In a particular example, the coverage area of the solder ball 222 accounts for more than 80% of the area of the circuit board pad 221 to increase the contact area between the solder ball 222 and the circuit board pad 221, thereby reducing the possibility of the solder ball 222 falling off the circuit board pad 221. It is understandable that, the amount of tin arranged on the circuit board pad 221 and the transfer rate of the solder paste are limited by the size of the stencil 90. Based on this problem, the size of the circuit board pad 221 is also restricted accordingly. Under the size of the chip 301 provided in this solution, the maximum length of the circuit board pad 221 is 75 μm, and the preferred diameter of the solder ball 222 is greater than or equal to 60 μm, thereby meeting the melting requirement of the solder ball 222 and the circuit board pad 221. Through the above-mentioned stencil printing process, the solder ball 222 is arranged on the circuit board pad 221, and the gold ball 332 is arranged on the chip pad 331. The gold ball 332 on the chip 301 is melted with the solder ball 222 on the circuit board 201, so as to achieve circuit conduction between the circuit board 201 and the chip 301.

The present application further provides a structure of a packaging assembly 10 after the chip 301 is conductively connected to the circuit board 201, as shown in FIGS. 3-4, wherein the packaging assembly 10 further comprises: a molding portion 501, a color filter 601 and a plurality of electronic components 401. After the circuit board 201 is conductively connected to the chip 301, corresponding molding portions 501 are provided on the front surface 211 and the back surface 212 of the circuit board to enhance the strength of the circuit board 201. The electronic components 401 or the like can be arranged on the front surface 211 and/or the back surface 212 of the circuit board, the electronic components 401 can be enclosed inside the molding portion 501, and the color filter 601 is arranged directly above the chip 301, wherein the color filter 601 covers the effective area 321 of the chip to filter out stray light. In a particular example, the molding portion 501 can form a color filter mounting position 531, and the color filter mounting position 531 is arranged on the upper end surface of the molding portion 501, wherein when the color filter 601 is arranged on the color filter mounting position 531, the color filter 601 covers the effective area 321 of the chip.

Furthermore, the circuit board 201 has a through hole 213 in the middle, the chip 301 is arranged on the circuit board 201, and the effective area 321 of the chip 301 corresponds to the through hole 213 of the circuit board, wherein the circuit board pads 221 are arranged on the back surface 212 of the circuit board, and the circuit board pad s221 are arranged around the through hole 213 of the circuit board. The chip pads 331 are arranged in the non-effective area 322 of the chip and located on the front surface 311 of the chip. When the chip 301 is arranged on the back surface of the circuit board 201, the chip pads 331 correspond to the circuit board pads 221 one by one, so that the chip 301 and the circuit board 201 are conductively connected. Particularly, the specific connection method between the chip 301 and the circuit board 201 has been described in detail in the previous text, and will not be repeated here. In a particular example, after the chip 301 is conductively connected to the circuit board 201, in order to ensure the stability of the overall structure, adhesive 232 is provided in the bonding area between the circuit board 201 and the chip 301 so as to prevent the chip 301 from falling off the circuit board 201.

Particularly, except for the bonding area between the chip and the back surface 212 of the circuit board, other areas of the back surface 212 of the circuit board can be coated accordingly by molding process to enhance the strength of the back surface 212 of the circuit board. Particularly, the portion on the back surface 212 of the circuit board formed by the molding process may be referred to as the back surface molding portion 512 of the circuit board. The back surface molding portion 512 of the circuit board is arranged around the through hole 213 of the circuit board, and the back surface molding portion 512 of the circuit board has certain size restrictions. Furthermore, the bottom surface of the back surface molding portion 512 of the circuit board can be arranged to be flush with the back surface 312 of the chip to provide corresponding protection for the chip 301. In a particular example, there is a first mounting area 214 between the inner edge of the back surface molding portion 512 of the circuit board and the edge of the through hole fixed on the back surface 212 of the circuit board, and there is a first gap 215 between the inner edge of the back surface molding portion 512 of the circuit board and the outer edge of the chip 301 fixed on the back surface 212 of the circuit board, i.e., the distance between the back surface molding portion 512 of the circuit board and the edge of the chip 301. At least a part of the front surface 211 of the circuit board corresponding to the first mounting area 214 is covered by the front surface molding portion 511, so as to provide a smooth mounting surface for bonding and conduction. At the same time, the first mounting area 214 is used for adhesive-dispensing, and the width of the first gap is ≤0.4 mm. The first gap 215 is mainly used for better accommodating the overflowed adhesive 232, at the time of subsequently applying adhesive 232 on the bonding area between the circuit board 201 and the chip 301, and then fixing the chip 301 on the circuit board 201 by bonding method, and it also can reduce the collision or extrusion of the back surface molding portion 512 and/or the circuit board 201 on the chip 301 during the subsequent baking or collision process of the packaging assembly 10.

In the present application, the molding portion 501 arranged on the front surface 211 of the circuit board may be referred to as the front surface molding portion 511 of the circuit board. The front surface molding portion 511 of the circuit board is arranged on the front surface 211 of the circuit board, wherein the electronic components 401 are arranged on the front surface 211 of the circuit board. In a particular example, the electronic components 401 may be arranged around the periphery of the through hole 213 of the circuit board. Furthermore, the front surface molding portion 511 of the circuit board can cover the electronic component 401 therein to provide corresponding protection for the electronic component 401 and improve the flatness of the packaging assembly 10. The front surface molding portion 511 of the circuit board can form a color filter mounting position 531 around the through hole 213 of the circuit board. The color filter mounting position 531 is arranged around the through hole 213 of the circuit board, wherein the upper surface of the color filter mounting position 531 is lower than the upper surface of the front surface molding portion 511 of the circuit board, i.e., a step portion is formed around the through hole 213 of the circuit board.

Furthermore, the step portion may comprise a first step portion 521 and a second step portion 522. The upper surface of the first step portion 521 can be used to support components such as a motor or an optical lens, and the second step portion 522 can be used as a color filter mounting position 531, which is mainly used to install the color filter 601. Particularly, the surface of the first step portion 521 is higher than the surface of the second step portion 522. The first step portion 521 covers the electronic component 401. The second step portion 522 can serve as the color filter mounting position 531. The height of the second step portion 522 can be 0.1 mm. The color filter 601 is installed on the color filter mounting position 531 so that the color filter 601 can be placed directly above the chip 301. Particularly, the upper surface of the color filter 601 installed on the color filter mounting position 531 is lower than the upper surface of the first step portion 521. In another example, the upper surface of the color filter 601 installed on the color filter mounting position 531 is flush with the upper surface of the first step portion 521. Preferably, in a particular example, the upper surface of the color filter 601 can be made lower than the upper surface of the first step portion 521, this arrangement can reduce the height of the packaging assembly 10 while further providing corresponding protection for the color filter.

For the structure of the packaging assembly 10 formed in the present application, as shown in FIGS. 2-3, a through hole 213 is arranged in the middle of the circuit board 201, a circuit board pad 221 is arranged on the back surface 212 of the circuit board, and a chip 301 is arranged on the back surface 212 of the circuit board and is conductively connected with the circuit board 201 to ensure the normal operation of the chip 301. Furthermore, in order to prevent the chip 301 from falling off from the back surface 212 of the circuit board, adhesive 232 is provided at a bonding area between the circuit board 201 and the chip 301 so as to increase the stability of the connection between the circuit board 201 and the chip 301. In order to enhance the strength of the overall structure after the circuit board 201 and the chip 301 are conductively connected, corresponding molding portions 501 are respectively provided on the front surface 211 and the back surface 212 of the circuit board. The molding portions 501 cover the electronic components 401 therein to protect the electronic components 401. Particularly, the electronic component 401 is arranged on the front surface 211 of the circuit board, and the front surface molding portion 511 of the circuit board covers the electronic component 401 therein. The front molding portion 511 of the circuit board forms the color filter mounting position 531 around the through hole 213 of the circuit board, and the color filter 601 can be installed on the color filter mounting position 531. At this time, the orthographic projection of the color filter 601 coincides with the effective area 321 on the chip 301, so as to play a corresponding filtering role on the light reaching the chip 301. The structure of the packaging assembly 10 formed by the above method can not only ensure the stability of the circuit conduction between the chip 301 and the circuit board 201, but also realize the miniaturization of the overall structure of the packaging assembly 10.

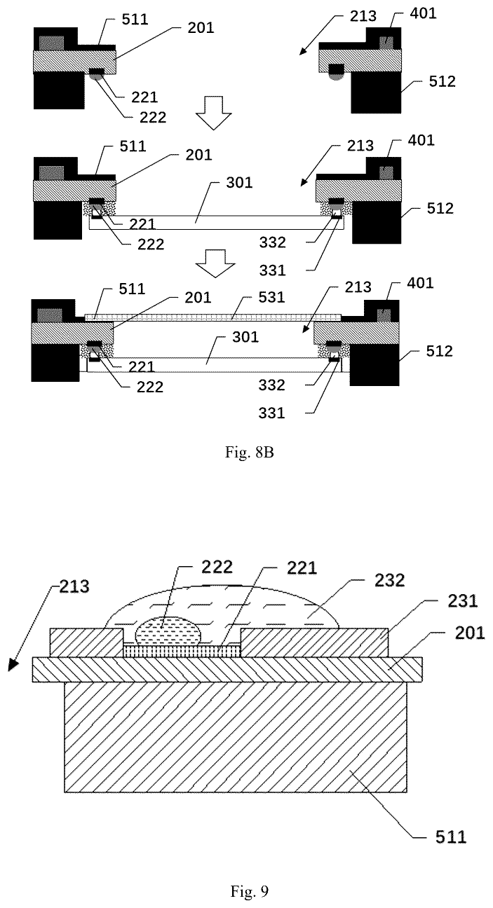

The present application further provides an assembling method of the packaging assembly 10, as shown in FIGS. 8A and 8B, wherein the method comprises the following steps: a) providing a circuit board 201, wherein a plurality of circuit board pads 221 are provided on one surface of the circuit board 201, and at least one solder ball 222 is implanted into the circuit board pad 221; b) providing a chip 301, wherein a plurality of chip pads 331 are provided on the chip 301, and at least one gold ball 332 is implanted into the chip pad 331; c) applying adhesive 232 onto the solder balls 222 of the circuit board pads 221; and d) aligning the chip pads 331 with the circuit board pads 221, and bonding and fixing the solder balls 222 of the circuit board pads 221 and the gold balls 332 of the chip pads 331 to conduct the circuit board 201 and the chip 301. Particularly, step b) and step c) are not prioritized, i.e., step b) can be performed first and then step c), or step c) can be performed first and then step c), or step b) and step c) can be performed simultaneously.

It can be understood that in some examples, after a plurality of solder balls 222 are implanted into the circuit board pads 221, adhesive 232 is first applied on the solder balls 222, and then the gold balls 332 are implanted into the chip pads 331, and then the chip pads 331 and the circuit board pads 221 are aligned, and the solder balls 222 and the gold balls 332 are bonded and fixed to conduct the circuit board 201 and the chip 301. In other examples, after a plurality of solder balls 222 are implanted into the circuit board pads 221, the gold balls 332 are first implanted into the chip pads 331, and then adhesive 232 is applied on the solder balls 222. The chip pads 331 and the circuit board pads 221 are aligned, and the solder balls 222 and the gold balls 332 are bonded and fixed to conduct the circuit board 201 and the chip 301. In other examples, the gold balls 332 are implanted into the chip pads 331, and the adhesive 232 is applied to the solder balls 222 simultaneously; and/or the gold balls 332 are implanted into the chip pads 331, and the solder balls 222 are implanted into the circuit board pads 221 simultaneously, and then the chip pads 331 and the circuit board pads 221 are aligned, and the solder balls 222 and the gold balls 332 are bonded and fixed to conduct the circuit board 201 and the chip 301, thereby shortening the working time and improving the assembly efficiency.

In particular, in the example of the present application, the adhesive 232 in step c) contains flux, the adhesive 232 is applied onto the circuit board pads 221 and covers the solder balls 222. The solder balls 222 are encapsulated in the adhesive 232, the flux in the adhesive 232 can prevent the solder balls 222 from being oxidized due to long-term exposure to the air, thereby facilitating the melting of the solder balls 222 with the gold balls 332.

Furthermore, as shown in FIG. 9, the step c) particularly comprises the steps of: eccentrically applying the adhesive 232 onto the circuit board pads 221 by adhesive dispensing process, so that the solder balls 222 are located on a side of the midline of the adhesive bead width which is close to the center of the circuit board 201. The adhesive 232 is squeezed and overflows when the circuit board 201 is assembled with the chip 301. Since the midline of the adhesive bead width of the adhesive 232 is closer to the outside of the circuit board 201 than the solder balls 222, in combination with the ink 231 arranged on the side close to the through hole 213 of the circuit board, the risk of the adhesive 232 overflowing inside and contaminating the effective area 321 of the chip 301 is reduced, and the adhesive 232 is caused to overflow to the outside of the chip 301. It is worth mentioning that, the thickness of the adhesive 232 is greater than the height of the solder balls 222, so that the adhesive 232 covers the solder balls 222 therein, thereby preventing the solder balls 222 from being oxidized, which is beneficial for the solder balls 222 to bond with the gold balls 332 to form a tin-gold compound 223, thereby conducting the circuit board 201 and the chip 301.

Furthermore, step d) particularly comprises the steps of: fixing the solder balls 222 of the circuit board pads 221 and the gold balls 332 of the chip pads 331 by thermal compression bonding, so that at least one of the solder balls 222 is melted with at least one of the gold balls 332 to form a conductive bonding area, and at the same time, the adhesive 232 is filled in the gap of the conductive bonding area to bond the circuit board 201 and the chip 301, thereby increasing the ability of the packaging assembly 10 to withstand external forces, reducing the risk of the chip 301 falling off, and improving the reliability of the packaging assembly 10. It is understandable that, the flux in the adhesive 232 helps the solder ball 222 to melt with the gold ball 332 and prevents the solder ball 222 from being oxidized, so as to improve the conductivity between the circuit board 201 and the chip 301. It is worth mentioning that during the thermal compression bonding process, the adhesive 232 can reduce the fluidity of tin, which helps to avoid the phenomenon of tin-bridging.

In particular, the temperature of the thermal compression bonding between the solder balls 222 and the gold balls 332 is controlled, and the temperature of the bonding process is step-wisely raised with a first bonding temperature and a second bonding temperature, wherein the first bonding temperature is used for a relatively short time, and the heating time of the second bonding temperature is 5 times more than that of the first bonding temperature. Particularly, the first bonding temperature is 100-200° C. and lasts for no more than Is so as to reduce the generation of bubbles in the adhesive 232 and increase the bonding area between the adhesive 232 and the circuit board 201 or the chip 301, so that the adhesive 232 fills the conductive bonding area between the chip 301 and the circuit board 201 to increase the bonding force. The second bonding temperature is 200° C.-300° C. and lasts for 5-30 s to strengthen the curing of the adhesive 232 to reliably bond the circuit board 201 and the chip 301, thereby improving the reliability of the packaging assembly 10.

Furthermore, step d) particularly comprises: forming a protrusion portion on the gold ball 332 of the chip pad 331, aligning it with the solder ball 222 of the circuit board pad 221, and extending the protrusion portion of the gold ball 332 into the solder ball 222 of the circuit board pad 221 to increase the contact area between the solder ball 222 and the gold ball 332, thereby improving the reaction rate of the solder ball 222, so that the solder ball 222 and the gold ball 332 are reliably bonded, thereby improving the conductivity between the circuit board 201 and the chip 301.

In particular, step a) particularly comprises the steps of: depositing solder paste on the circuit board pads 221 by stencil printing, so that the printing direction of the stencil 90 is consistent with the arrangement direction of the circuit board pads 221, thereby reducing the phenomenon of tin-bridging and insufficient tin. The solder paste is formed into the solder ball 222 by reflow soldering and implanted into the circuit board pads 221, thereby preventing the solder ball 222 from being oxidized and reducing the bending and deformation of the circuit board 201.

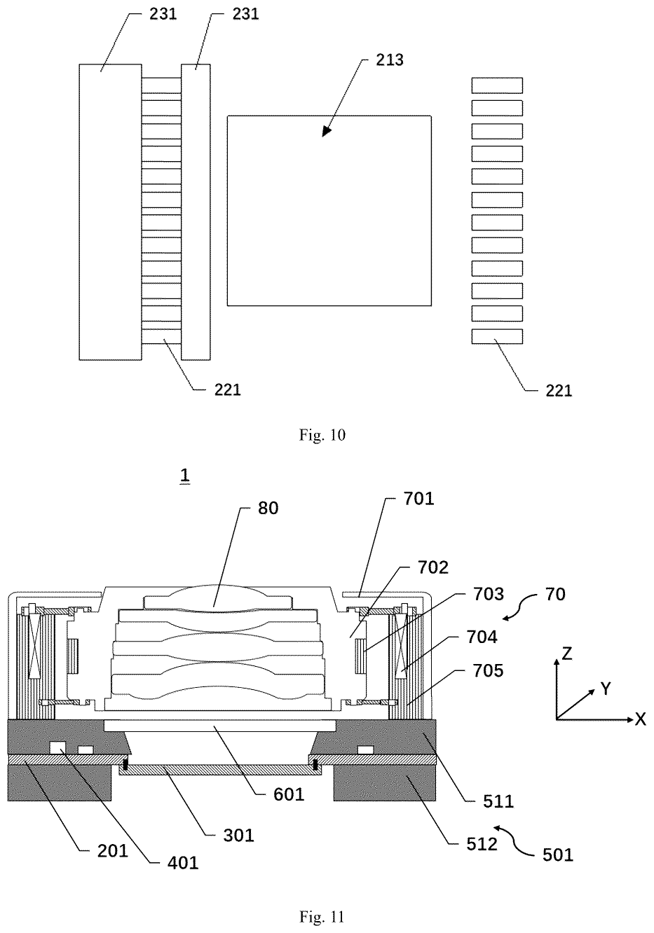

Particularly, as shown in FIG. 10, step a) particularly comprises: protrudingly arranging the ink structure 231 on the circuit board 201 to form a groove, so that the circuit board pad 221 is at least partially accommodated in the groove, and the solder ball 222 covers at least 80% of the area of the circuit board pad, so that the solder ball 222 can be accommodated in the groove formed by the ink structure 231 on the circuit board 201. Particularly, the ink structure 231 is arranged on both sides of the circuit board pad 221 close to and away from the through hole 213 of the circuit board. It can be understood that, the stencil 90 is arranged on the circuit board 201, and the ink structure 231 is located between the stencil 90 and the circuit board 201, so that there is a gap between the stencil 90 and the circuit board 201. The thickness of the ink structure 231 is less than 15 μm, which can prevent the tin ball of the solder ball 222 from overflowing from the gap between the stencil 90 and the circuit board 201 so as to avoid tin-bridging.

Furthermore, step a) further comprises step a1): integrally forming a front molding portion 511 of the circuit board on the front surface of the circuit board 201, the front molding portion 511 of the circuit board covers the electronic components 401 arranged on the front surface 211 of the circuit board, which is beneficial to improve the flatness of the packaging assembly 10; and integrally forming a back molding portion 512 of the circuit board on the back surface of the circuit board 201, so that the back molding portion 512 of the circuit board is arranged on the outer side of the circuit board pad 221, thereby providing a middle position of the back surface 212 of the circuit board for installing the chip 301. It is worth mentioning that, compared with molding the front molding portion 511 and the back molding portion 512 of the circuit board at the same time, molding the front molding portion 511 and the back molding portion 512 of the circuit board separately can help reduce the difficulty of molding, avoid defects such as under-injection in the molding channel cavity, thereby improving the flatness of the packaging assembly 10.

The step a) further comprises step a2): forming a through hole 213 on the circuit board 201, wherein the through hole 213 passes through the central area of the circuit board 201, and the front molding portion 511 of the circuit board is arranged in a ring shape around the through hole. It can be understood that, the size of the through hole 213 is larger than the size of the effective area 321 of the chip 301, so that the effective area 321 is completely exposed in the through hole 213. The farther the inner edge of the through hole 213 is from the effective area 321 of the chip 301, the more conducive it is to reducing the risk of stray light and improving imaging quality. Preferably, the through hole 213 is formed on the circuit board 201 by laser cutting, and ultrasonic cleaning is performed before bonding to reduce the cutting dust remaining in the through hole 213.

Furthermore, the assembling method of the packaging assembly 10 further comprises step e): installing the color filter 601 on the color filter mounting position 531 on the front molding portion 511 of the circuit board to filter out stray light and improve imaging quality.

The present application further provides an anti-shake camera module 1 assembled using the structure of the packaging assembly 10, as shown in FIG. 11. Particularly, the anti-shake camera module 1 comprises: a packaging assembly 10, a chip driver, an optical lens 80, etc. Particularly, the chip driver is arranged on the packaging assembly 10, and the optical lens 80 is arranged directly above the packaging assembly 10, and external light reaches the packaging assembly 10 through the optical lens 80. Furthermore, the structure of the packaging assembly 10 in the present application adopts an arrangement combining the front molding portion 511 and the back molding portion 512, so that the chip 301 and the circuit board 201 can be bonded through a molding process, thereby effectively reducing the volume and weight of the packaging assembly 10. Particularly, the weight of the packaging assembly 10 in the present application can be controlled at about 0.266 g. Compared with the conventional COB (chip of board) packaging method, the weight of the packaging assembly 10 can be reduced by about 13%. Under the existing size of the camera module, the driving force provided by the chip driver remains unchanged, so that the camera module 1 using the packaging assembly 10 structure can significantly improve the adjustable stroke of the chip 301. With the current trend of miniaturization of camera modules, the structure of the packaging assembly 10 provided in this solution can not only meet the requirements of large chip movement range, but also has certain advantages in the miniaturization of the overall structure. It is a commonly selected technical direction of chip anti-shake in the industry.

Furthermore, as shown in FIG. 11, the camera module 1 may further comprise a lens motor 70, which is arranged on the optical lens 80, wherein the lens motor 70 is mainly used to drive the optical lens 80 to move, particularly, the lens motor 70 can drive the optical lens 80 to move along the direction of the optical axis, i.e., the Z-axis direction, so as to achieve focusing during the shooting process of the camera module 1. In a particular example, the chip driver can drive the chip 301 to move in a plane perpendicular to the optical axis, i.e., in the X/Y direction, and the lens motor 70 can drive the optical lens 80 to move along the Z-axis direction (i.e., the direction of the optical axis). Through the cooperation between the optical lens 80 and the chip 301, the imaging quality of the camera module 1 can be effectively improved. In another particular example, the lens motor 70 can drive the optical lens 80 to move along the direction of the optical axis, i.e., the Z-axis direction, and can also drive the optical lens 80 to move in the plane perpendicular to the optical axis, i.e., the X/Y direction, particularly, the chip driver can also drive the chip 301 to move along the X/Y direction, and the optical lens 80 and the chip 301 cooperate with each other to achieve anti-shake of a larger stroke of the camera module 1.

Particularly, the lens motor 70 in the camera module 1 can select a spring-type structure, and the optical lens 80 is arranged inside the lens motor 70 to drive the optical lens 80 to move. In a particular example, the lens motor 70 may comprise structures such as a magnet 704, a coil 703, a spring, a lens carrier 702 and a base 705, wherein the optical lens 80 is fixed on the lens carrier 702, the coil 703 is fixed on the lens carrier 702, the magnet 704 is arranged around the coil 703, and the spring is arranged between the base 705 and the lens carrier 702. Furthermore, the lens motor 70 further comprises a motor housing 701, which encloses other components constituting the lens motor 70 therein to provide corresponding protection for the components of the lens motor 70. In order to better utilize the internal space of the lens motor 70, the magnet 704 can be arranged inside the motor housing 701 and around the coil 703 on the lens carrier 702 so as to achieve better fit between the magnet 704 and the coil 703.

Further, as shown in FIG. 11, the structure of the packaging assembly 10 provided in the present application can be arranged on the lower surface of the base 705 of the lens motor 70, wherein the lower surface of the base 705 of the lens motor 70 is fixed to the upper surface of the packaging assembly 10 according to the present application. Particularly, the upper surface of the packaging assembly 10 is located on the first step portion 521 of the front molding portion 511. The front molding portion 511 adopts a molding process so that its upper surface maintains a certain flatness, which is conducive to fixing the first step portion 521 of the front molding portion 511 and the base 705 of the lens motor 70 together. For example, the lens motor 70 may be fixed to the packaging assembly 10 by gluing or other fixing methods, and the motor housing 701 covers the outside of the packaging assembly 10 to provide corresponding protection for the packaging assembly 10. The structure of the packaging assembly 10 adopted in this solution has the advantages of miniaturization and lightness, and providing it at the bottom of the lens motor 70 can significantly reduce the height of the camera module 1 and meet the requirements of miniaturization of the camera module 1.

As shown in FIG. 11, particularly, the present application provides a camera module 1 with the structure of the packaging assembly 10, and the optical axis of the optical lens 80 arranged on the lens motor 70 is consistent with the center of the chip 301 on the structure of the packaging assembly 10, so that the chip 301 can receive the light entering the optical lens 80. During the imaging process of the camera module 1, according to a pre-set program, the lens motor 70 can drive the optical lens 80 to perform position correction so that as much light as possible passing through the optical lens 80 can reach the chip 301 of the packaging assembly 10. Furthermore, by utilizing the structure of the packaging assembly 10 provided in this solution, the size of the chip 301 can be increased to about 1/1.7 inch. By utilizing the packaging method and conduction method provided above, while improving the imaging quality of the camera module, the miniaturization of the overall structure can be effectively guaranteed, thus catering to the trend of miniaturization of camera modules.

The basic principles, main features and advantages of the present application are described above. Those skilled in the art should understand that, the present application is not limited to the above-mentioned examples. The above-mentioned examples and the specification only describe the principles of the present application. Various changes and improvements may be made to the present application without departing from the spirit and scope of the present application. These changes and improvements all fall within the protection scope of the present application. The protection scope of the present application is defined by the appended claims and their equivalents.

1. A packaging assembly comprising:
a circuit board and a chip, wherein the circuit board is provided with a through hole, and the chip is arranged corresponding to the through hole of the circuit board,
wherein a plurality of circuit board pads are provided on the circuit board, and at least one solder ball is arranged on each of the circuit board pads, and a plurality of chip pads are provided on the chip, and at least one gold ball is arranged on the chip pad, and the chip pad corresponds to the circuit board pad, and at least one gold ball is melted with at least one solder ball to form a conductive bonding area to conduct the circuit board and the chip; and
there are gaps between a plurality of conductive bonding areas where the gold balls are melted with the solder balls, and the gaps are filled with adhesive.

2. The packaging assembly according to claim 1, wherein the adhesive contains flux and covers the solder balls.

3. The packaging assembly according to claim 2, wherein the adhesive connects the circuit board and the chip, and completely fills the gaps between the plurality of conductive bonding areas where the gold balls are melted with the solder balls.

4. The packaging assembly according to claim 2, wherein the adhesive is arranged around the through hole of the circuit board and covers the circuit board pads, and the adhesive has a adhesive bead width, and the solder balls are arranged on a side of the midline of the adhesive bead width which is close to the through hole of the circuit board, so that the adhesive can cover the solder balls therein.

5. The packaging assembly according to claim 4, wherein the thickness of the adhesive is greater than the height of the solder ball, and the thickness of the adhesive is greater than or equal to 20 μm.

6. The packaging assembly according to claim 1, wherein an ink structure is provided on the circuit board, and the ink structure is respectively provided on both sides which are close to and away from the through hole of the circuit board, and the ink structure is protrudingly provided on the circuit board pad to form a groove, and the circuit board pad is at least partially accommodated in the groove.

7. The packaging assembly according to claim 6, wherein the solder ball is arranged on the circuit board pad, and the solder ball covers at least 80% of the area of the circuit board pad, so that the solder ball is accommodated in the groove formed by the ink structure.

8. The packaging assembly according to claim 1, wherein the gold ball on the chip pad has a protrusion portion, and the protrusion portion extends into the interior of the solder ball on the circuit board pad to increase the contact area between the solder ball and the gold ball.

9. The packaging assembly according to claim 8, wherein the circuit board pads are arranged corresponding to the chip pads, and the center distance between at least some adjacent circuit board pads is less than 150 μm.

10. The packaging assembly according to claim 1, wherein the packaging assembly further comprises a molding portion which is integrally formed on the circuit board, and the molding portion comprises a front molding portion formed on the front surface of the circuit board and a back molding portion formed on the back surface of the circuit board.

11. The packaging assembly according to claim 10, wherein the back molding portion is arranged on the back surface of the circuit board, and the back molding portion can be used to strengthen the strength of the circuit board, and the lower surface of the back molding portion is lower than the back surface of the chip.

12. The packaging assembly according to claim 11, wherein the front molding portion is arranged in a ring shape around the through hole of the circuit board, and the front surface of the circuit board provided with the circuit board pad is covered by the front molding portion.

13. A camera module comprising:
a lens motor, and
the packaging assembly according to claim 1;
wherein the lens motor is arranged on the upper surface of the packaging assembly so that external light can reach the interior of the packaging assembly through the lens motor.

14-26. (canceled)
